(19) United States
(12) Patent Application Publication
(10) Pub. No.: US 2007/0093037 A1
(43) Pub. Date: Apr. 26, 2007

(54) Vertical structure semiconductor devices and method of fabricating the same

(75) Inventors: TingGang Zhu, Somerset, NJ (US); Marek Pabisz, Quakertown, PA (US); Milan Pophristic, Princeton, NJ (US)

Correspondence Address: PATENT DOCKET ADMINISTRATOR;LOWENSTEIN SANDLER PC, 65 LIVINGSTON AVENUE, ROSELAND, NJ, 07068, US

(73) Assignee: Velox Semicondutor Corporation

(21) Appl. No.: 11/586,948

(22) Filed: Oct. 25, 2006

Related U.S. Application Data
(60) Provisional application No. 60/730,472, filed on Oct. 26, 2005.

(51) Int. Cl. H01L 21/30; H01L 21/46

(52) U.S. Cl. 438/458

(57) ABSTRACT

The present invention provides a vertical structure semiconductor device and method of fabricating the same. The method comprises providing a sapphire substrate bonded to a bottom surface of a semiconductor wafer, and a metal coated to the top surface of the semiconductor wafer. The method also comprises securely bonding a thermal and electrical conductive substrate to the wafer and removing the sapphire substrate from the wafer by laser lift-off to expose the bottom surface of the wafer. Furthermore, a metal is deposited to the exposed bottom surface of the wafer.

### CROSS-REFERENCE TO RELATED APPLICATIONS

This application claims the benefit of U.S. Provisional Patent Application No. 60/730,472 filed Oct. 26, 2005, the entire disclosure of which is incorporated herein by reference.

### FIELD OF THE INVENTION

The present invention relates generally to a field of semiconductor devices. More specifically, the present invention relates to vertical structure semiconductor devices and method of fabricating the same.

### BACKGROUND OF THE INVENTION

It is very common in the art to grow nitride based semiconductor devices on sapphire. However, due to the high thermal resistance and electrical insulating property of sapphire, a sapphire substrate is typically not desirable for high current density operation in the application of the nitride based semiconductor devices. Thus, the sapphire is removed by a well known sapphire substrate laser-liftoff process, and replaced by a dissimilar substrate such as copper, silicon or diamond. This process is used in nitride based semiconductor devices, typically such as GaN light-emitting diodes on which LEDs are grown on sapphire. The removal of sapphire solves two main purposes. First, it improves thermal conductivity of the device and allows for fabrication of vertical devices, thus improving forward voltage and potentially breakdown voltage The spreading resistance of the vertical device is close to zero compare to the large spreading resistance of the lateral device. This spreading resistance of the lateral device in the high current conduction lead to higher forward voltage. Replacement of the sapphire with higher thermal conductivity substrate will improve the device thermal performance. Second, it enhances light extracting. For the certain light emitting area, removing the sapphire and depositing highly reflective metal, such as Ag, Ti, Al on the separated semiconductor surface, this approach could help to reflect the light out of semiconductor and therefore enhance light extraction. This well known laser-lift off technique is described in U.S. Pat. No. 6,071,795 and U.S. Pat. No. 6,740,604 B2, both of which are incorporated herein by reference.

FIG. 1 illustrates a conventional process flow to make a vertical nitride semiconductor device such as a Gallium Nitride (GaN) schottky device 100 fabricated on an insulating sapphire substrate 102. This device can be used for applications such as Light Emitting Diode (LED), Laser Diode (LD), Hetero-junction Bipolar Transistor (HBT), High Electron Mobility Transistor (HEMT) and many more. The GaN Schottky device 100 has been fabricated by conventional process without formation of the metallic contact, cathode, on top of GaN film 101 as shown in FIG. 1. However, a metallic contact of anode 103 is formed on the top surface of the GaN film 101. After the process is completed, a sub-carrier wafer (or supporting substrate) 104, such as silicon, is bonded to a surface of the GaN device 100 opposite to the sapphire substrate 102 as shown in FIG. 1. The next process is to remove the sapphire 102 substrate by laser lift-off (LLO) or other technology, to expose the bottom side of GaN film 101. Subsequently, thereafter a thermal and electrical conductive substrate 105 such as a silicon or copper is bonded to the exposed bottom side of the GaN film 101. Thus, the whole wafer undergoes a metal deposition process to form cathode in the substrate 105, replacing the sapphire substrate 102 in the device 100. Then, the sub-carrier 104 is removed, the vertical GaN Schottky device 100 is realized. However, this approach involves two substrates, the sub-carrier 104 & cathode 105), especially the bonding process of 104 to anode induce unnecessary complexity. Since the substrate 104 has to be removed in the later process, the bonding interface should not be affected by the subsequent process, otherwise it will cause difficulty of removing it.

Thus, due to these limitations of conventional techniques, there is a need in the art to provide a semiconductor chip device and a method for fabricating the same to achieve improved device performance by improving forward and reverse characteristics, reduced chip size and provide a cost effective device.

### BRIEF DESCRIPTION OF THE DRAWINGS

FIG. 1 illustrates the process flow to make vertical GaN semiconductor device according to the prior art;

FIG. 2A illustrates the process flow to achieve the vertical GaN semiconductor device in accordance with one embodiment of the present invention; and

FIG. 2B illustrates an exemplary vertical GaN Schottky diode of the device of FIG. 2A prior to the removal of the sapphire substrate.

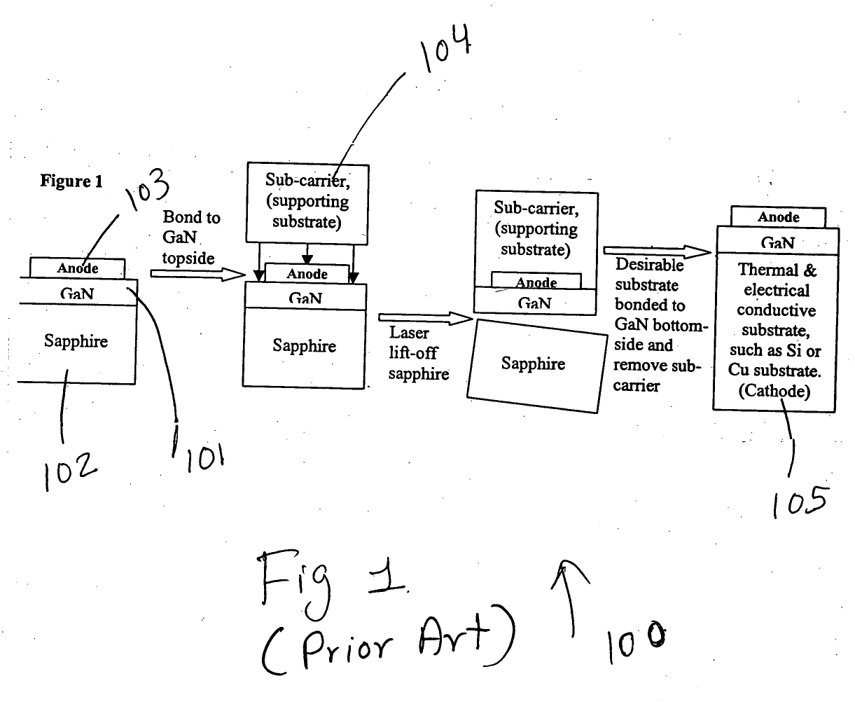

It is understood that the attached drawings are for the purpose of illustrating the concepts of the invention and may not be to scale.

### DETAILED DESCRIPTION OF THE INVENTION

Embodiments of the present invention comprise combining laser-liftoff and bonding processes to realize a semiconductor device on a desired substrate to achieve improved forward and reverse characteristics, reduced chip size and competitive cost.

Typically, a semiconductor device, such as a GaN Schottky diode requires >10 A current maximum current (which corresponds to the current density of 600 A/cm²⁾) during the forward conduction mode. If the heat generated during the forward current conduction cannot be quickly dissipated, the heat will increase the device temperature. Since most semiconductor material properties, such as carrier mobility, are a function of the temperature, the increased temperature may cause the severe degradation on the device performance. To reduce the thermal effect on the device performance, thermal conductivity of the device can be improved. GaN material itself has very good thermal property; it has very high thermal conductivity. However, the device is usually grown on 15-17 mil thick poorly thermal-conductive sapphire. Thus, as discussed above, removing the sapphire by laser lift-off (or other technology) and bonding the free-standing GaN Schottky diode to thermal conductive substrate, such as Silicon or Copper, will greatly improve heat conduction for the GaN Schottky device.

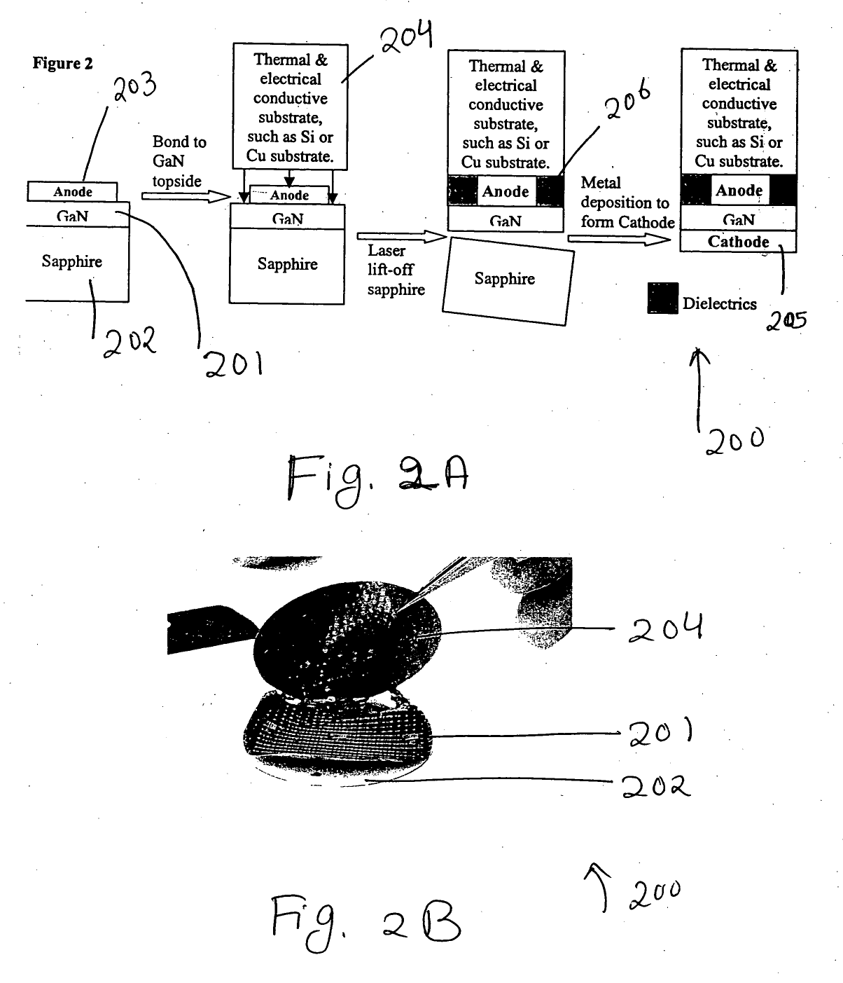

FIG. 2A illustrates the process flow to achieve a vertical GaN semiconductor device 200 such as a GaN Schottky device fabricated on an insulating sapphire substrate 202, according to an embodiment of the present invention. The sapphire substrate 202 is preferably 350 um to 450 um thick. As discussed above, the GaN Schottky device 200 has been fabricated by a conventional process without formation of the Cathode on top of a GaN film 201 as shown in FIG. 2A. The GaN 201 is desirably 6-30 um thick. A metallic contact anode 203 is formed on the top surface of the GaN film 201. After the process completed, a thermally and electrically conductive substrate 204, is securely bonded to the top surface of the GaN film 201 with the anode 203 of GaN device 100 alloyed (thermally alloyed) to the substrate 204 Preferably the substrate 204 and the anode 203 is thermally bonded, such as using solder to bond the anode 203 on the metal coated substrate 204. The substrate 204 is bonded such that it cannot be removed from the GaN Schottky device 200 without destructing the device. The substrate comprises of materials such as silicon or copper or aluminum or silver, etc. and has a thickness varying preferably in the range of 250 um to 450 um. Note, the thermal and electrical substrate 204 is positioned opposite to the sapphire substrate 202. Also, as shown in FIG. 2A, preferably a dielectric material 206 such as oxides, nitrides, for example SiO, SiN, is deposited in some portion of the anode 203. The dielectric material 206 has a thickness desirably between 0.1 to 2 um and is utilized to insulate the device edge conduction.

An exemplary vertical GaN Schottky device 200, illustrated as a GaN Schottky diode prior to the sapphire removal is illustrated in FIG. 2B with an electrical and thermal substrate/sub-carrier 204 securely bonded to the top surface of the GaN film 201. The sub-carrier 204 desirably comprises of silicon having a thickness of preferably in the range of 250 to 400 um. The GaN Schottky diode is fabricated on the sapphire substrate 202 having a range desirably between 300 um to 450 um.

The next process as shown in FIG. 2A is to remove the sapphire substrate 202 preferably by laser lift-off, to expose the bottom surface of GaN film 201, thus decomposing or separating the bottom surface from the sapphire 202. The laser radiation beam is submitted through the sapphire substrate 202 targeting at an interface between the GaN film 201 and the sapphire substrate 202. The laser radiation energy is optimized to be absorbed at the interface or in the region in the vicinity of the interface and absorbed radiation energy induces a decomposition of GaN film 201 at the interface. Subsequently, thereafter, the whole wafer undergoes a metal deposition process i.e. after removing the sapphire substrate 202, the device 200 is bonded on the electrical and thermal substrate 204, which is preferably loaded in vacuum chamber for metallization by e-beam evaporation, thermal evaporation or sputtering. This forms the metallic contact cathode 205 at the decomposed or separated bottom surface of the GaN film 201, replacing the sapphire substrate 202 of the device 200. Thus, the vertical GaN Schottky device 200 is formed. The current flow in this vertical structure is from anode to cathode. Thus, by removing the sapphire and replacing it with highly thermal conductive substrate, the thermal resistance of the whole device 200 could be significantly reduced. Furthermore, by reducing the thermal resistance (the key parameter to determine the surge current) could improve the surge current capability. The forward voltage could be reduced since the spreading resistance, which is encountered in the lateral device, is eliminate in the design of vertical structure. The vertical structure allows more space in the anode design A multiple guard ring arrangement could be employed to eliminate the electrical field crowding and therefore reducing the device leakage current.

Furthermore, the electrically insulating sapphire makes the GaN Schottky design with lateral current conduction beneficial. This approach indeed makes the lateral design occupy more wafer area. Because in lateral design both anode and cathode will on the same side, say top side, the wafer area occupied is area of anode plus area of cathode. In the vertical design, anode and cathode are on different side, top and bottom, so wafer area occupied is virtually same as anode or cathode area. Thus, the lateral design occupies more wafer area. Since the forward voltage drop in conduction mode is proportional to the active area of the Schottky contact, the vertical current conduction design will greatly reduce the chip size required as in the lateral conduction design. Removing the sapphire with laser lift-off (or other technology) and bond the free-standing GaN Schottky diode on electrical conductive substrate, such as Silicon or Copper, will realize the vertical current conduction and reduce the chip size and hence will improve cost effectiveness. In addition, as discussed above, the vertical design of the diode will leave more room to put so called guard rings near the edge of the Schottky metal, improving breakdown voltage.

In an alternate embodiment of the present invention, one of several treatment processes are preferably applied to the device 200 prior to forming the metallic contact cathode 205 at the bottom surface of the GaN film 201. Preferably, one of the treatment process comprises cleaning the decomposed or separated bottom surface of the GaN film 201 with wet chemicals such ass KOH, NH4OH, or Buffer HF etc. Another preferred treatment process comprises dry etching the separated bottom surface of the GaN film 201 with gases such as CF4, O2, Cl2, BCl3, or any gas containing these elements. Alternatively, both of the above described processes may be applied in treating the separated bottom surface of the GaN film 201. Usually the exposed bottom surface of the GaN film 201 after separation is very smooth, it is not suitable for metal deposition adhesion. By the treatment as described above it not only to promote the metal contact adhesion, but also to improve the electrical contact by reducing the GaN film 201 and metal contact resistance.

The completed body of the semiconductor device 200 could preferably be packaged by solder, epoxy on the TO-220, TO-252, TO-247, TO-3 package. Since this vertical structure 200 has both top and bottom side accessible for electrical contacts, the anode side or cathode side could be direct contact on the ground plate of package for the ease of packaging design.

The present invention is described based on fabricating GaN semiconductor device. However, various compound semiconductors made of group III-V semiconductors can be structured using the described procedures.

Even though various embodiments that incorporate the teachings of the present invention have been shown and described in detail herein, those skilled in the art can readily devise many other varied embodiments that still incorporate these teachings without departing from the spirit and the scope of the invention.

1. A method of forming a semiconductor structure comprising:
providing a semiconductor wafer having a sapphire layer bonded to a bottom surface of the wafer and a metal coated to a top surface of the wafer to form a first electrode;
securely bonding a thermally and electrically conductive substrate to the top surface of the wafer such that the first electrode is alloyed to the substrate;
removing the sapphire layer from the wafer to expose the bottom surface of the wafer; and
depositing a metal to the exposed bottom side of the wafer to form a second electrode.

2. The method of claim 1 wherein said removing step further comprises irradiating the bonded bottom surface with an electromagnetic radiation through the sapphire layer.

3. The method of claim 2 further comprising depositing a dielectric material in some portion of the first electrode.

4. The step of claim 1 wherein said bonding comprises soldering the first electrode of the wafer to the substrate.

5. The step of claim 1 wherein said depositing comprises loading the sapphire free wafer in a vacuum chamber for metallization by e-beam evaporation, thermal evaporation or sputtering.

6. A method of forming a semiconductor structure comprising:
providing a semiconductor wafer having a sapphire layer bonded to a bottom surface of the wafer and a metal coated to a top surface of the wafer to form a first electrode;
securely bonding a thermally and electrically conductive substrate to the top surface of the wafer such that the first electrode is alloyed to the substrate;
removing the sapphire layer from the wafer to expose the bottom surface of the wafer;
chemically treating the exposed bottom surface of the wafer; and
depositing a metal to the exposed chemically treated bottom surface of the wafer to form a second electrode.

7. The method of claim 6 wherein said removing step further comprises irradiating the bonded bottom surface with an electromagnetic radiation through the sapphire layer.

8. The step of claim 6 wherein said bonding comprises soldering the first electrode of the wafer to the substrate.

9. The step of claim 6 wherein said depositing comprises loading the sapphire free wafer in a vacuum chamber for metallization by e-beam evaporation, thermal evaporation or sputtering.

10. The method of claim 6 further comprising depositing a dielectric material in some portion of the first electrode.

11. The method of claim 6 wherein said chemically treating step comprises wet chemical cleaning the exposed bottom surface of the wafer.

12. The method of claim 6 wherein said chemically treating step comprises dry etching the exposed bottom surface of the wafer.

13. A sapphire free semiconductor structure comprising:
a semiconductor wafer comprising gallium nitride (GaN) having a top surface and a bottom surface, said wafer comprising a first metal deposited on the top surface to form a first electrode and a second metal deposited on the bottom surface to form a second electrode;
a thermally and electrically conductive substrate securely bonded to said top surface of the semiconductor wafer such that the first electrode is alloyed to the substrate.

14. The structure of claim 13 wherein said first electrode comprises one of anode or cathode.

15. The structure of claim 13 wherein said second electrode comprises one of said anode or cathode.

16. The structure of claim 13 wherein said substrate comprises a material selected from a group consisting of silicon copper, aluminum and silver.

17. The structure of claim 13 further comprises a dielectric material deposited on a portion of the first electrode.

18. The structure of claim 13 wherein said dielectric material comprise a material selected from a group consisting of oxides.

19. The structure of claim 13 wherein said dielectric material comprise a material selected from a group consisting of nitrides.

20. A semiconductor device comprising
a semiconductor wafer comprising gallium nitride (GaN) having a first metal deposited on a top surface of the wafer to form a first electrode and a sapphire layer deposited on the bottom surface of the wafer; wherein said device is formed by securely bonding a thermally and electrically conductive substrate to the top surface of the wafer such that the first electrode is alloyed to the substrate, removing the sapphire layer from the wafer to expose the bottom surface of the wafer, and depositing a metal to the exposed bottom side of the wafer to form a second electrode.
